(19) United States
(12) Patent Application Publication
(10) Pub. No.: US 2021/0185828 A1
(43) Pub. Date: Jun. 17, 2021

(54) FLUX TRANSFER APPARATUS

(71) Applicant: SHINKAWA LTD., Tokyo (JP)

(72) Inventor: Kohei SEYAMA, Tokyo (JP)

(73) Assignee: SHINKAWA LTD., Tokyo (JP)

(21) Appl. No.: 16/762,504

(22) PCT Filed: Nov. 2, 2018
(86) PCT No.: PCT/JP2018/040788

§ 371 Date: May 8, 2020

(30) Foreign Application Priority Data
Nov. 9, 2017 (JP) 2017-216029

(51) Int. Cl. H05K 3/34; B23K 3/06; B23K 3/08

(52) U.S. Cl. CPC H05K 3/34; B23K 3/0692; B23K 2101/40; B23K 3/085; B23K 3/082

(57) ABSTRACT

This flux transfer apparatus (10) comprises: a stage (12) having a recessed portion (13) for collecting flux (51); a flux pot (20) which is an annular member having a through hole (21) into which the flux (51) is introduced, which reciprocates along a top surface (14) of the stage (12) to supply the flux (51) that has been introduced into the through hole (21) into the recessed portion (13), and which levels off the top surface of the flux using a bottom surface (22); and a cooling mechanism (30) for cooling the stage (12). By this means, a rise in the temperature of the stage in the flux collecting apparatus is suppressed.

### BACKGROUND OF THE INVENTION

### Field of the Invention

The present invention relates to a structure of a flux collecting apparatus. More specifically, the present invention relates to a structure of a flux collecting apparatus used in a flux transfer apparatus that transfers flux to a protruding electrode of an electronic component.

### Description of Related Art

In recent years, a flip chip bonding method in which a protruding electrode (e.g., a solder bump) is formed in an electronic component such as a semiconductor, the electronic component is picked up to be reversed, the protruding electrode is placed on an electrode pad of a printed substrate, heating to a high temperature is performed to melt the solder of the protruding electrode, and the electronic component is bonded to the printed substrate, has been more and more broadly used. In the flip chip bonding method, in order to facilitate the bonding property between the solder and the electrode pad, a method of transferring flux (oxide film remover or surfactant) to the top surface of the protruding electrode (solder bump) and then placing the protruding electrode on the electrode pad is used.

At the time of transfer of the flux to the protruding electrode of the electronic component, an apparatus that dips the protruding electrode of the electronic component into a thin flux layer collected in a recessed portion to transfer the flux to the tip of the protruding electrode is used. The apparatus includes a stage provided with the recessed portion that collects the flux and a flux pot having a through hole into which the flux is introduced, makes the flux pot reciprocate along the top surface of the stage to supply the flux to the recessed portion of the stage and make the liquid surface of the flux collected in the recessed portion smooth using the bottom surface of the flux pot (for example, see Patent Document 1).

### PRIOR ART DOCUMENTS

### Patent Documents

Patent document 1: WO 2016/075982

### SUMMARY OF THE INVENTION

### Issue(s) to be Solved by the Invention

However, it is known that flux may change in quality, such as being solidified, if the temperature rises. Therefore, at the time when the protruding electrode of the electronic component is dipped into the flux collected in the recessed portion of the stage, it is necessary to cool down the electronic component, a bonding tool to which the electronic component is attached and fixed, a heater, etc., to a temperature at which the flux in standby in the flux pot does not change in quality, and suppress the rise of temperature of the flux in standby in the flux pot at the time of dipping. However, since it takes time to cool down the temperature of the bonding tool, the heater, etc., from the temperature at the time of bonding, there is an issue that the lower the temperature of the bonding tool and the heater at the time of dipping, the lower the productivity has become.

Therefore, the objective of the present invention is to suppress the rise of the temperature of the stage in the flux collecting apparatus.

### Means for Solving the Issue

A flux collecting apparatus according to the present invention includes: a stage having a recessed portion for collecting flux; a flux pot, which is an annular member having a through hole into which the flux is introduced, reciprocates along a top surface of the stage to supply the flux having been introduced into the through hole into the recessed portion, and levels off a top surface of the flux using a bottom surface; and a cooling mechanism for cooling the stage.

In the flux collecting apparatus, the cooling mechanism may be a Peltier element.

### Inventive Effect

The present invention is capable of suppressing the rise of the temperature of the stage in the flux collecting apparatus.

### BRIEF DESCRIPTION OF THE DRAWINGS

FIG. 1A is a plan view illustrating a configuration of a flux collecting apparatus in an embodiment of the present invention.

FIG. 1B is a plan cross-sectional view illustrating a configuration of a flux collecting apparatus in an embodiment of the present invention.

FIG. 2A is a plan view illustrating an operation of the flux collecting apparatus illustrated in FIG. 1A.

FIG. 2B is a plan cross-sectional view illustrating an operation of the flux collecting apparatus illustrated in FIG. 1B.

FIG. 3 is an explanatory diagram illustrating a state in which a bonding tool at a high temperature is lowered to the flux collecting apparatus illustrated in FIGS. 1A and 1B.

FIG. 4 is a graph illustrating changes of height and temperature of the bonding tool over time during the time of performing flip chip bonding using a bonding apparatus including the flux collecting apparatus illustrated in FIGS. 1A and 1B.

### DESCRIPTION OF THE EMBODIMENTS

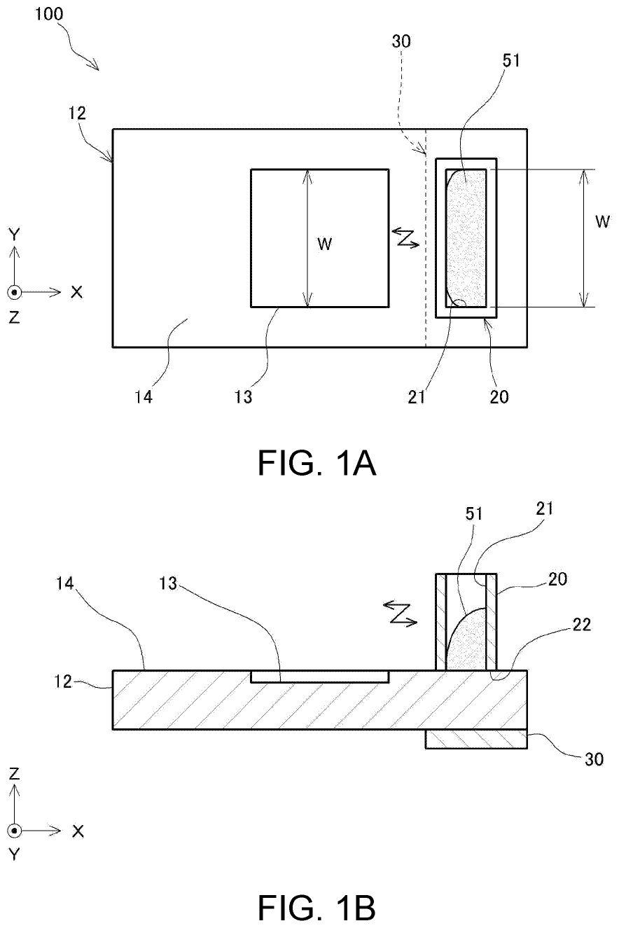

In the following, a flux collecting apparatus 100 of the embodiment is described with reference to the drawings. As shown in FIG. 1A and FIG. 1B, the flux collecting apparatus 100 includes a stage 12 having a recessed portion 13 that collects flux, a flux pot 20 which supplies flux 51 to the recessed portion 13 and levels off a top surface of the flux using a bottom surface 22 thereof, and a cooling mechanism 30 for cooling the stage 12. The flux pot 20 moves reciprocally in the X direction by a driving mechanism not shown herein. The descriptions in the following are made with the reciprocal movement direction of the flux pot 20 as the X direction, a perpendicular direction thereof as the Y direction, and an up-down direction as the Z direction.

As shown in FIG. 1A and FIG. 1B, the stage 12 has the recessed portion 13 which is recessed from a top surface 14 to collect the flux. The flux 13 has a width W and extends along the reciprocal movement direction (X direction). The depth of the recessed portion 13 is a depth in which a protruding electrode of an electronic component such as a semiconductor can be dipped into, and may be about 10 to 20 μm, for example.

As shown in FIGS. 1A and 1B, the flux pot 20 is an annular member having a through hole 21 penetrating in the Z direction along which the flux 51 is introduced, supplies the flux 51 having been introduced into the through hole 21 to the recessed portion 13 from a stage side opening of the through hole 21, and levels off the top surface of the flux using the bottom surface 22 thereof. The through hole 21, like the recessed portion 13, is a rectangular hole with the width W.

In addition, on the lower side of the stage 12, the cooling mechanism 30 is installed. The cooling mechanism 30, for example, may be a heat dissipating fan, and may be one using a Peltier element.

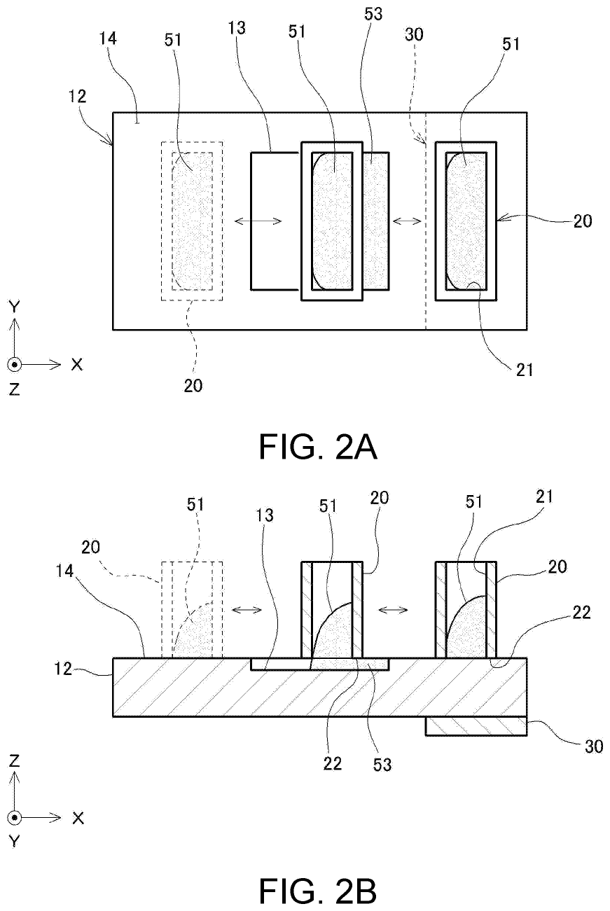

In the following, the operating of the flux collecting apparatus 100 with such configuration will be described with reference to FIG. 2A and FIG. 2B. As shown in FIG. 2A and FIG. 2B, in an initial state, the flux pot 20 is located at the upper side of the cooling mechanism 30 on the X direction plus side of the recessed portion 13. In such state, the flux 51 is filled into the through hole 21 of the flux pot 20. Since the bottom surface 22 of the flux pot 22 is in close contact with the top surface 14 of the stage 12, the flux 51 does not flow to the outside from the through hole 21, but is maintained in an inner side space of the through hole 21.

Then, the flux pot 20 is moved by the driving mechanism not shown herein toward the X direction minus side. When the through hole 21 of the flux pot 20 comes above the recessed portion 13, the flux 51 filled in the through hole 21 falls into the recessed portion 13 of the stage 12. The top surface of flux 51 having fallen into the recessed portion 13 levels off by the bottom surface 22 of the flux pot 20 and becomes flux 53 whose depth is substantially the same as the depth of the recessed portion 13. The flux pot 20 moves reciprocally in the X direction above the recessed portion 13 for several times, so that the entire recessed portion 13 is filled by the flux 53 with a uniform thickness.

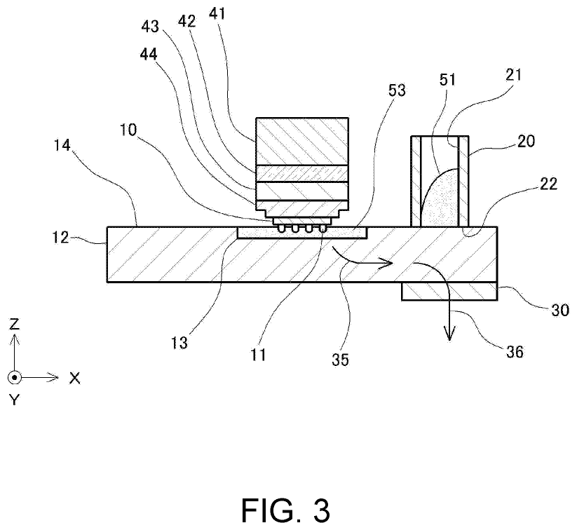

As shown in FIG. 3, if the recessed portion 13 is filled by the flux 53, the flux pot 20 is returned to the initial position by the driving mechanism not shown herein.

If the flux pot 20 returns to the initial position, a bonding head 41 is moved above the recessed portion 13 by the driving mechanism not shown herein. On the lower surface of the bonding head 41, a heater 44 and a bonding tool 44 sandwiching a heat insulating material 42 are installed. In addition, a semiconductor die 10 is attached and fixed to the lower surface of the bonding tool 44. A solder bump 11 is configured on the lower surface of the semiconductor die 10. At this time, the temperature of the bonding tool 44 and the heater 43 becomes about 100° C., and the temperature of the semiconductor die 10 and the solder bump 11 also becomes about 100° C.

The bonding head 41 is lowered by a driving apparatus not shown herein, the solder bump 11 dipped into the flux 53 in the recessed portion 13, and the flux 53 is transferred to the top surface of the solder bump 11. At this time, the stage 12 is heated by radiant heat from the semiconductor die 10, the bonding tool 44, and the heater 43 at about 100° C. The heat that heats the stage 12, as indicated by arrows 35 and 36 shown in FIG. 3, flows from the lower portion of the recessed portion 13 toward the cooling mechanism 30 and is discharged to the outside from the cooling mechanism 30.

Accordingly, since the flux collecting apparatus 100 of this embodiment discharges the radiant heat received from the semiconductor die 10, the bonding tool 44, and the heater 43 at the time when these components approach the surface 14 of the stage to the outside from the cooling mechanism 30, even if the temperature of the bonding tool 44 and the heater 43 becomes about 100° C., which is higher than the conventional 60° C., the flux collecting apparatus 100 can suppress the flux 51 filled in the flux pot 21 from changing in quality due to an excessive rise of the temperature of the stage 12.

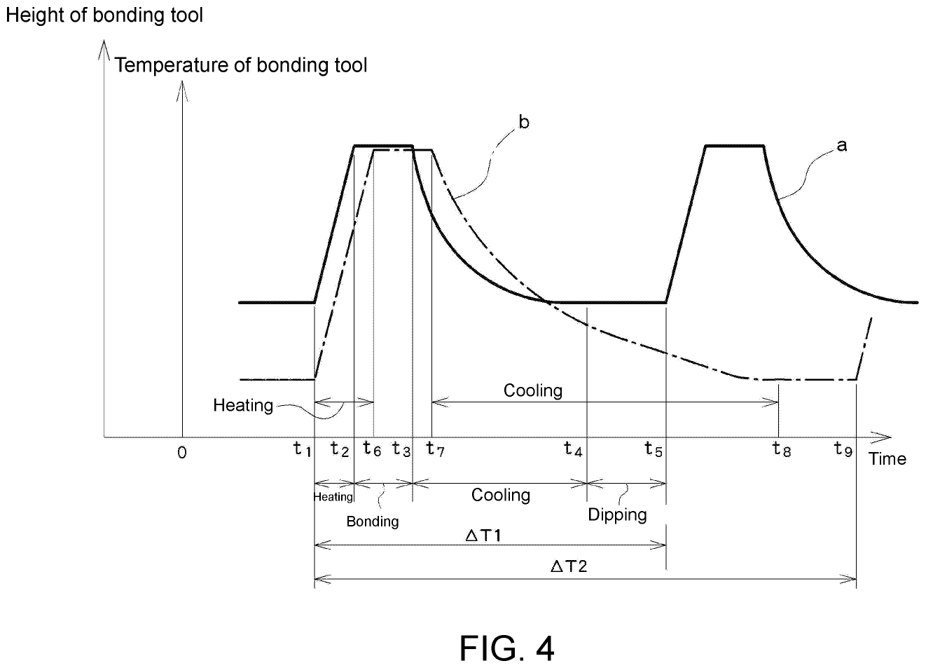

In addition, since the heating temperature at the time of bonding is a temperature of about 250° C. that melts the solder bump 11, in the case where flip chip bonding is performed using the flux collecting apparatus 100 of the embodiment, the dipping into the flux 53 can be performed with the temperature of the bonding tool 44 and the heater 43 being about 100° C., which is higher than the conventional 60° C. Therefore, the time for cooling the bonding tool 44 and the heater 43 (time t4−time t3, as shown in FIG. 4) is shorter than the time (time t8−time t7, as shown in FIG. 4) in the case where a flux collecting apparatus 100 of the conventional technology is used. Accordingly, the cycle time of bonding can be significantly shortened to AT1 from AT2 of the conventional technology shown in FIG. 4.

As described above, since the flux collecting apparatus 100 of the embodiment can suppress the rise of the temperature of the stage 12 at the time when the bonding tool 44 and the heater 43 of a high temperature approach the stage 12, the cooling temperature of the bonding tool 44 and the heater 43 can be higher than the conventional technology, so the cooling time of the bonding tool 44 and the heater 43 can be reduced and the tact time can be reduced.

### DESCRIPTION OF REFERENCE SYMBOLS

10: semiconductor die; 11: solder bump; 12: stage; 13: recessed portion; 14: top surface; 20: flux pot; 21: through hole; 22: bottom surface; 30: cooling mechanism; 35, 36: arrows; 41: bonding head; 42: heat insulating material; 43: heater; 44: bonding tool; 51, 53: flux.

1. A flux transfer apparatus, comprising:
a stage having a recessed portion for collecting flux in a central portion of a top surface;
a flux pot, which is an annular member having a through hole into which the flux is introduced, reciprocates along the top surface of the stage to supply the flux having been introduced into the through hole into the recessed portion, and levels off a top surface of the flux using a bottom surface; and
a cooling mechanism for cooling the stage,
wherein the flux transfer apparatus dips a tip of a protruding electrode of an electronic component into the flux collected in the recessed portion to transfer the flux to the tip of the protruding electrode,
the flux pot returns to an initial position at a periphery of the recessed portion at a time of transfer of the flux, and
the cooling mechanism is installed to a lower side of the initial position of the stage.

2. The flux transfer apparatus as claimed in claim 1, wherein the cooling mechanism is a Peltier element.
